(19) United States
(12) Patent Application Publication
(10) Pub. No.: US 2006/0038953 A1
(43) Pub. Date: Feb. 23, 2006

(54) Electro-optical device, color filter, and electronic apparatus

(75) Inventor: Hidekuni Moriya, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/179,768

(22) Filed: Jul. 13, 2005

(30) Foreign Application Priority Data
Aug. 20, 2004 (JP) 2004-240441

(51) Int. Cl. G02F 1/1343

(52) U.S. Cl. 349/144

(57) ABSTRACT

An electro-optical device includes a plurality of sub-pixels two-dimensionally arranged in a row direction of a display region and in a column direction thereof orthogonal to the row direction. Each group of five sub-pixels constitutes a display pixel, including three sub-pixels that are arranged in the row direction and two sub-pixels that are adjacent to the three sub-pixels in the column direction, the sub-pixels in one display pixel outputting different color light components, and the display pixels are arranged two-dimensionally in a substantially honeycomb shape.

### BACKGROUND

The present invention relates to an electro-optical device, to a color filter, and to an electronic apparatus.

In order to achieve a high image quality in a liquid crystal display, a CRT display, a projector, or the like, methods have been known in which a color reproduction range is expanded by using a fourth color light component, such as cyan (C), yellow (Y), magenta (M), or the like, in addition to three primary colors including red (R), green (G), and blue (B). For example, Japanese Unexamined Patent Application Publication No. 2001-306023 discloses a color filter in which sub-pixels (dots) of four colors including R, G, B, and C are arranged in a square shape. Further, Japanese Unexamined Patent Application Publication No. 2002-6303 discloses a color filter in which dots of RGB and W (white) are arranged in a square shape and the arrangements of the colored portions of adjacent pixels are reversed.

On the other hand, in recent years, an electro-optical device having a configuration in which a large range of colors can be reproduced by performing five-primary-color display with an increased number of primary colors has been suggested. However, when multi-primary-color display is performed, the application of the pixel arrangement structure according to the related art is impossible. Therefore, a new pixel arrangement structure corresponding to the five-primary-color display is required.

### SUMMARY

An advantage of the invention is that it provides an electro-optical device that has a new pixel arrangement structure, thereby achieving five-primary-color display with high definition and high image quality. Further, another advantage of the invention is that it provides a color filter having the new pixel arrangement structure.

According to a first aspect of the invention, an electro-optical device includes a plurality of sub-pixels two-dimensionally arranged in a row direction of a display region and in a column direction thereof orthogonal to the row direction. Each group of five sub-pixels constitutes a display pixel, including three sub-pixels that are arranged in the row direction and two sub-pixels that are adjacent to the three sub-pixels in the column direction, the sub-pixels in one display pixel outputting different color light components, and the display pixels are arranged two-dimensionally in a substantially honeycomb shape.

As such, the three sub-pixels arranged in the row direction and the two sub-pixels adjacent to the three sub-pixels in the column direction constitute each display pixel, and the display pixels are arranged in the honeycomb shape (delta type). As a result, the pixel arrangement structure in which the display pixels can be densely arranged without gaps can be realized. Therefore, it is possible to provide an electro-optical device in which display can be performed with high definition and high image quality and the aperture ratio of the pixel can be enhanced.

In addition, according to the arrangement of the honeycomb shape, one pixel is surrounded by adjacent six pixels and is arranged so as to be deviated by a ½ pixel in the row direction or column direction with respect to the adjacent pixel. Here, the ‘electro-optical device’ collectively includes a light-emitting device for converting electrical energy into optical energy, in addition to a device having an electro-optical effect that the refractive index of a material is changed by an electric field and thus the transmittance is changed.

In the electro-optical device according to the first aspect of the invention, it is preferable that the sub-pixels have substantially rectangular shapes in plan view and are arranged in a square lattice shape in the display region. That is, in accordance with the first aspect of the invention, as regards the arrangement of the sub-pixels constituting the display pixel, the square lattice arrangement, which has been adopted in an electro-optical device for three-primary-color display, is generally used as it is. Therefore, the wiring structure of the panel does not need to be changed significantly. As a result, the display can be achieved with high image quality while suppressing a manufacturing cost from being increased.

Further, in the electro-optical device according to the first aspect of the invention, it is preferable that two adjacent display pixels in the row direction have reversed external shapes. For example, display pixels in which the sub-pixels are arranged in a substantially L shape and display pixels in which the sub-pixels are arranged in a substantially inverted L shape can be densely arranged without gaps in the plane.

Further, in the electro-optical device according to the first aspect of the invention, it is preferable that the sub-pixels have substantially rectangular shapes in plan view and are arranged in a honeycomb shape in the display region. That is, as regards the arrangement of the sub-pixels constituting the display pixel, the honeycomb arrangement (delta arrangement) adopted in the electro-optical device for the three-primary-color display is generally used as it is. Therefore, the wiring structure of the panel does not need to be changed significantly. As a result, the display can be achieved with the high image quality while suppressing the manufacturing cost from being increased.

Further, the electro-optical device according to the first aspect of the invention may further include a color filter having a plurality of colored portions that are arranged so as to correspond to the respective sub-pixels. From the five colored portions included in each display pixel, four colored portions may be chromatic colored portions and one colored portion may be an achromatic colored portion or a colored portion having a color corresponding to a light source.

According to this configuration, an electro-optical device for four-primary-color display can be implemented. The display pixel includes the sub-pixel of the achromatic color or the color of the light source, such that the transmittance can be enhanced, which results in bright display.

In the electro-optical device according to the first aspect of the invention, it is preferable that the chromatic colored portions include colored portions of red, green, and blue. Further, the chromatic colored portions may include a colored portion of cyan, yellow, or magenta. According to this configuration, the color reproduction range, including the color reproduction range of the three-primary-color display can be expanded by adding another color. Further, according to the five-primary-color display including cyan, yellow, or magenta, an electro-optical device having expressiveness corresponding to a printed matter can be constructed. In addition, it is preferable to include cyan from cyan, yellow, and magenta. In an xy chromatic diagram, a cyan region has a large range that cannot be reproduced by the three-primary-color display of R, G, and B, and thus display fidelity can be effectively enhanced with the addition of cyan.

In the electro-optical device according to the first aspect of the invention, it is preferable that each sub-pixel include a light-emitting element. Further, the electro-optical device according to the first aspect of the invention may further include a liquid crystal panel that has a liquid crystal layer interposed between a pair of substrates. That is, the electro-optical device can be constructed as a liquid crystal display device or an EL (electroluminescent) display device. That is, it is preferable to constitute an electro-optical device having electro-optical elements that performs the control of turning on the color light components set according to the arrangement of the sub-pixels and emitted from the sub-pixels.

Preferably, the electro-optical device includes a signal processing circuit (image processing circuit) for converting image signals, including color information of R, G, and B, into image signals corresponding to five kinds of sub-pixels, respectively. Specifically, when the sub-pixels arranged in the display region correspond to R, G, B, C, and Y, the signal processing circuit generates and outputs image signals of R, G, B, C, and Y from image signals of R, G, and B. When the electro-optical device includes the signal processing circuit, a RGB signal generally used in a personal-computer can be displayed with five primary colors.

Specifically, the signal processing circuit may have the configuration in which an LUT (Lookup Table) for converting the RGB signal into an RGBCY signal is provided. According to this configuration, when a predetermined RGB signal is inputted, the RGBCY signal after the signal conversion can be obtained only by referring to the LUT.

According to a second aspect of the invention, a color filter includes a plurality of colored portions two-dimensionally arranged in a row direction and in a column direction thereof orthogonal to the row direction. Five colored portions constitute a colored portion group, including three colored portions that are arranged in the row direction and two colored portions that are adjacent to the three colored portions in the column direction, the colored portions in one colored portion group being different in color, and the colored portion groups are arranged two-dimensionally in a substantially honeycomb shape.

In the color filter having the above-described configuration, the colored portion groups, each having colored portions of five colors can be densely arranged in the color filter without gaps. Therefore, it is possible to implement a color filter that can constitute an electro-optical device with high definition and high brightness.

In the color filter according to the second aspect of the invention, it is preferable that the colored portions have substantially rectangular shapes in plan view and are arranged in a square lattice shape in plan view. According to this configuration, the color filter can have the same arrangement of the colored portions as the color filter used for the conventional electro-optical device for the three-primary-color display, so that a color filter corresponding to five primary colors can be achieved at low cost. In addition, it is preferable that adjacent colored portion groups in the row direction have reversed external shapes.

Further, in the color filter according to the second aspect of the invention, it is preferable that the colored portions have rectangular shapes in plan view and are arranged in a honeycomb shape in plan view. According to this configuration, the color filter can have the same arrangement of the colored portions as the color filter used for the conventional electro-optical device for the three-primary-color display, such that a color filter corresponding to five primary colors can be achieved at low cost.

According to a third aspect of the invention, an electronic apparatus includes the above-described electro-optical device.

Examples of the electronic apparatus may include information processing devices, such as, for example, a cellular phone, a mobile information terminal, a watch, a word processor, a personal computer, and the like. Further, examples of the electronic apparatus may include a television having a large display screen and a large monitor. The electro-optical device is used for a display unit of the electronic apparatus, such that an image can be displayed by display colors of a broad wavelength band close to natural light.

### BRIEF DESCRIPTION OF THE DRAWINGS

The invention will be described with reference to the accompanying drawings, wherein like numbers reference like elements, and wherein:

FIG. 1 is a diagram schematically showing a configuration of an image display system according to a first embodiment of the invention;

FIG. 2 is a plan view showing a configuration of a liquid crystal panel according to the first embodiment of the invention;

FIG. 3 is an exploded perspective view of the liquid crystal panel according to the first embodiment of the invention;

FIG. 4 is a plan view partially showing a configuration of a color filter according to the first embodiment of the invention;

FIG. 5 is a diagram showing spectral characteristics of a color filter;

FIG. 6 is a diagram showing spectral characteristics of a fluorescent tube that is used for a backlight;

FIG. 7 is a diagram showing spectral characteristics of a liquid crystal panel;

FIG. 8 is a chromaticity diagram of a liquid crystal panel;

FIG. 9 is a plan view partially showing a configuration of a color filter according to a second embodiment of the invention;

FIG. 10 is a plan view partially showing a configuration of a color filter according to a third embodiment of the invention;

FIG. 11 is a plan view partially showing a configuration of an organic EL display device according to a fourth embodiment of the invention; and

FIG. 12 is a perspective view showing a configuration of an example of an electronic apparatus.

### DETAILED DESCRIPTION OF EMBODIMENTS

Hereinafter, preferred embodiments of the invention will be described with reference to the accompanying drawings.

Moreover, in the drawings, the scale of each layer or member has been adjusted in order to have a recognizable size.

### First Embodiment

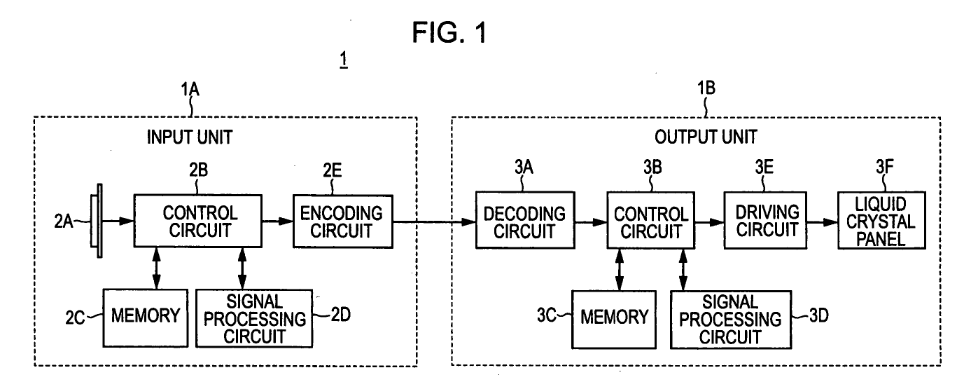

A first embodiment of the invention will be now described with reference to FIGS. 1 to 4.

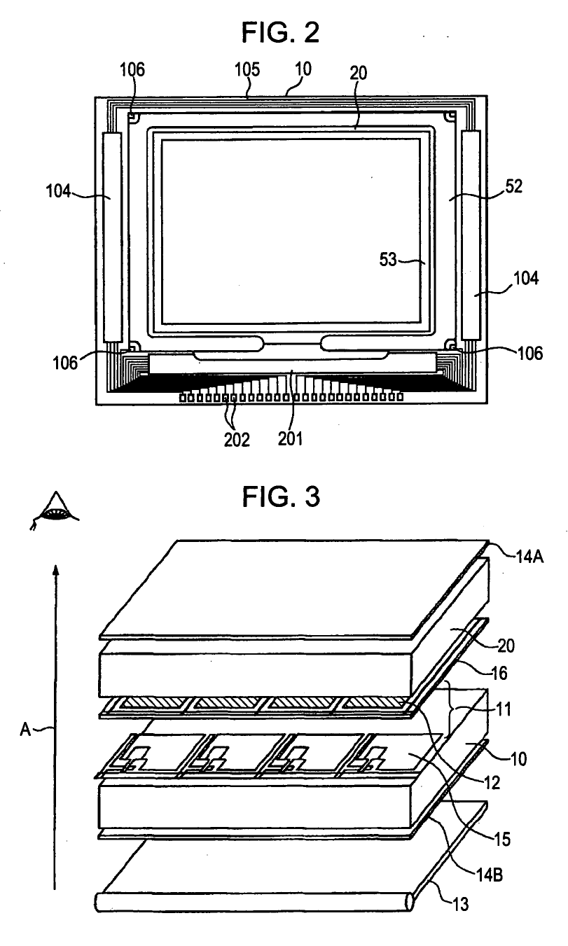

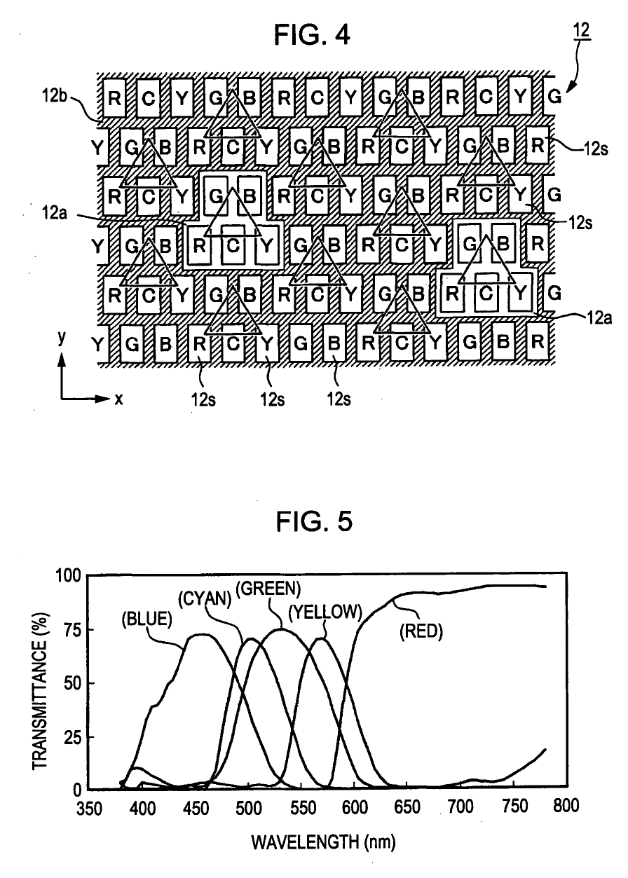

FIG. 1 is a block diagram showing the configuration of an image display system according to the first embodiment of the invention. FIG. 2 is a plan view showing respective parts of a liquid crystal panel included in the image display system as viewed from a counter substrate. FIG. 3 is an exploded perspective view of the liquid crystal panel. FIG. 4 is a plan view showing the configuration of a color filter shown in FIG. 3.

As shown in FIG. 1, an image display system 1 primarily has an input unit 1A and an output unit 1B. Images acquired by the input unit 1A are displayed by the output unit 1B, which is an electro-optical device.

The input unit 1A includes an input sensor 2A, a control circuit 2B, a memory 2C, a signal processing circuit 2D, and an encoding circuit 2E. The output unit 1B includes a decoding circuit 3A, a control circuit 3B, a memory 3C, a signal processing circuit 3D, a driving circuit 3E, and a liquid crystal panel 3F.

In the input unit 1A, the input sensor 2A is an imaging unit having a charge transfer element, such as a photoelectric conversion element, a CCD (charge coupled device), or the like, and is controlled by the control circuit 2B. The input sensor 2A outputs an electrical signal according to the amount of received light of the photoelectric conversion element. The signal processing circuit 2D is connected to the control circuit 2B. The signal processing circuit 2D includes an AID conversion unit and an image forming unit. An analog signal inputted from the input sensor 2A is quantized by the A/D conversion unit and is converted into a digital signal. In addition, the signal processing circuit 2D performs a noise removal process or a gain adjustment process, along with the A/D conversion process. In addition, the image forming unit performs a white balance correction or gamma correction with respect to the digital signal outputted from the A/D conversion unit and generates a luminance signal Y having a digital value and digital image data of color-difference signals Cb and Cr (YLv signal) and an RGB signal for each pixel. The control circuit 2B allows digital image data to be stored in the memory 2C.

The encoding circuit 2E is supplied with digital image data from the control circuit 2B, performs an encoding process on the digital image data, and transmits a code stream to the output unit 1B. Specifically, the encoding circuit 2E compresses the digital image data by using a discrete cosine transform, a wavelet transform, run-length coding, Huffman coding, or the like, and transmits compressed image data to the decoding circuit 3A of the output unit 1B.

Next, the decoding circuit 3A, which is supplied with the code stream from the encoding circuit 2E through a transmission path, decodes digital image data with a format according to a coding method of the encoding circuit 2E to reproduce digital image data, and transmits reproduced digital image data to the control circuit 3B.

The control circuit 3B converts received digital image data into an image signal by the signal processing circuit 3C and outputs the converted image signal to the driving circuit 3E. In addition, the memory 3C is used for a work memory used during signal processing or a frame memory for holding a predetermined image signal.

The image signals, which are generated in the control circuit 3B, are image signals according to the configuration of the liquid crystal panel 3F, and the liquid crystal panel 3F according to the present embodiment is an electro-optical device that can perform five-primary-color display. Therefore, the image signals become image signals of the respective colors including R (red), G (green), B (blue), C (cyan), and Y (yellow). That is, when digital image data is inputted as a general three-primary-color signal, the conversion from the three primary colors to the five primary colors is performed by the signal processing circuit 3D. In the conversion of the number of primary colors, the conversion is performed by automatically referring to a conversion table (LUT) with respect to the conversion from the three primary colors to the five primary colors. In addition, when input digital image data is a pixel data group arranged in a square lattice shape and display pixels of the liquid crystal panel are arranged in a delta arrangement, resampling from the square lattice arrangement to the delta arrangement (resolution conversion) is performed prior to the conversion of the number of primary colors.

Then, these image signals are converted into driving signals by the driving circuit 3E to be supplied to the respective display pixels (switching elements) of the liquid crystal panel 3F.

Next, as shown in FIGS. 2 and 3, the liquid crystal panel 3F has a configuration in which a TFT array substrate 10 and a counter substrate 20 are bonded to each other via a sealing material 52 and a liquid crystal layer 11 is sealed in a region defined by the sealing material 52. A light-shielding film (peripheral sacrificial portion) 53, which is made of a light-shielding material, is formed inside a formation region of the sealing material 52. In a peripheral circuit region outside the sealing material 52, a data line driving circuit 201 and external circuit mounting terminals 202 are formed along one side of the TFT array substrate 10, and scanning line driving circuits 104 are formed along two sides adjacent to that one side. On the last side of the TFT array substrate 10, a plurality of wiring lines 105 that connect the scanning line driving circuits 104 and 104 to each other are provided. In addition, inter-substrate conducting members 106 are provided at corner portions of the counter substrate 20, such that the TFT array substrate 10 and the counter substrate 20 are electrically connected to each other.

Therefore, the liquid crystal panel 3F is an active-matrix-type transmissive liquid crystal panel that uses thin film transistors (hereinafter, referred to as TFTs) as switching elements.

In addition, as shown in FIG. 3, a plurality of pixel electrodes 15 are provided on the inner surface of the TFT array substrate 10 (the surface facing the liquid crystal layer 11), and a common electrode 16 is provided on the entire inner surface of the counter substrate 20. A color filter 12 is provided on one surface of the common electrode 16 facing the counter substrate 20. Further, upper and lower polarizers 14A and 14B are provided on the outer surfaces of the TFT array substrate 10 and the counter substrate 20, and a backlight (illumination unit) is provided on the back surface of the panel (the outer surface of the polarizer 14B).

The TFT array substrate 10 and the counter substrate 20 are mainly formed with a transparent substrate made of glass or plastic. The pixel electrodes 15 and the common electrode 16 are made a light-transmissive conductive material, such as ITO (indium tin oxide). The pixel electrodes 15 are connected to the TFTs (thin film transistors) formed on the TFT array substrate 10, respectively. An electric field is applied to the liquid crystal layer 11 between the common electrode 16 and the pixel electrodes 15 through switching of the TFTs when the driving signals are inputted from the driving circuit shown in FIG. 2. Transmitted light is controlled through the alignment control of the liquid crystal.

The liquid crystal layer 11 contains liquid crystal molecules whose alignment states are changed in accordance with the voltage applied between the common electrode 16 and the pixel electrodes 15. A liquid crystal mode of the invention is not particularly limited, but may use any one of a TN (twisted nematic) mode, in which the liquid crystal molecules between the substrates with the liquid crystal layer 11 interposed therebetween are twisted by 90 degrees to be aligned, and a VAN (vertical alignment nematic) mode, in which the liquid crystal molecules are aligned in the normal direction to the substrate.

The backlight 13 has a light source and a light guiding plate. Light emitted from the light source is uniformly spread by the light guiding plate and the spread light is outputted as illumination light in a direction indicated by A. The light source may be constructed by using a fluorescent tube or an LED (light-emitting diode), and the light guiding plate made of a resin material, such as an acrylic resin, may be molded in a plate shape, such that a prism shape can be formed on the plate surface.

FIG. 4 is a plan view partially showing the configuration of the color filter 12. The color filter 12 includes a plurality of colored portions 12s that are arranged in a row direction (x direction in the drawing) and a column direction (y direction in the drawing) and a black matrix 12b that two-dimensionally divides the respective colored portions 12. In the color filter 12, colored portions 12s corresponding to five primary colors (G, B, R, C, and Y) are cyclically arranged in a row direction. The colored portions 12s form colored portion groups 12a (colored portion groups indicated by triangles) each having five colored portions 12s for different colors. On the surface of the color filter 12, the colored portion groups 12a are arranged in a zigzag pattern in a honeycomb shape in plan view. According to the present embodiment, each colored portion group 12a has three continuous colored portions 12s (R, C, and Y) in the row direction and two colored portions 12S (G and B) adjacent to the three colored portions 12s in the column direction.

In addition, although not shown in FIG. 3, the color filter 12 is provided on substantially the entire surface of the display region of the liquid crystal panel 3F. On the TFT array substrate 10 of the liquid crystal panel 3F, the respective pixel electrodes 16 are provided at locations that two-dimensionally overlap the respective colored portions 12s of the color filter 12. That is, a sub-pixel of the liquid crystal panel 3F is formed in a two-dimensional region of one pixel electrode 16 and one colored portion 12s arranged to face one pixel electrode 16, and the display pixel of the liquid crystal panel 3F has the sub-pixels including the five colored portions 12s constituting each colored portion group 12a.

FIG. 5 is a diagram showing wavelength selection characteristics of the color filter 12. As shown in FIG. 5, the transmittance distribution of the respective colors including B (blue), C (cyan), G (green), Y (yellow), and R (red) correspond to the colored portions 12s of five colors, respectively. Illumination light incident on each sub-pixel is converted into a specific color light component by the colored portion 12s provided in the sub-pixel and is outputted as display light.

In addition, as a method of manufacturing the color filter 12, a known method of manufacturing a color filter can be applied. For example, the colored portions corresponding to the respective colors including B, C, G, Y, and R can be formed by exposing and developing a coated resist with a photolithography technology. Alternatively, the color filter can be formed by using an inkjet method (a liquid droplet ejection method). In the inkjet method, materials for forming the colored portions corresponding to the respective colors including B, C, G, Y, and R are deposited on the substrate in a predetermined pattern from an ejection head in which liquid materials of the respective colors are filled, dried and solidified. As a result, solid colored portions are formed.

In addition, in the case of the color filter having the configuration in which the colored portions 12s of five colors are arranged, a degree of freedom in an arrangement order is obtained (in the case of the color filter having the configuration in which the colored portions of three colors are arranged, in any arrangement order, a degree of freedom is not obtained due to periodicity and symmetry). That is, FIG. 4 shows an example in which the colored portions are arranged in the order of GB (upper portion) and RCY (lower portion) from the upper left side in the drawing. However, various arrangements including this arrangement may be considered and, among these, any one arrangement may be used.

Further, the present embodiment relates to a so-called delta type in which the sub-pixels constituting the display pixel are arranged in the honeycomb shape, and thus the wiring structure of the data lines with respect to the TFTs, which are provided so as to correspond to the pixel electrodes 16, corresponds to the delta type. In addition, the color filter 12 is obtained by arranging the colored portions 12s of five colors periodically. Alternatively, a wiring structure in which the sub-pixels of five colors are connected through the data lines arranged in a zigzag pattern (the same method as the data line) or a wiring structure in which adjacent sub-pixels of two colors are alternately connected to the data lines (two-color rotation method) may be used.

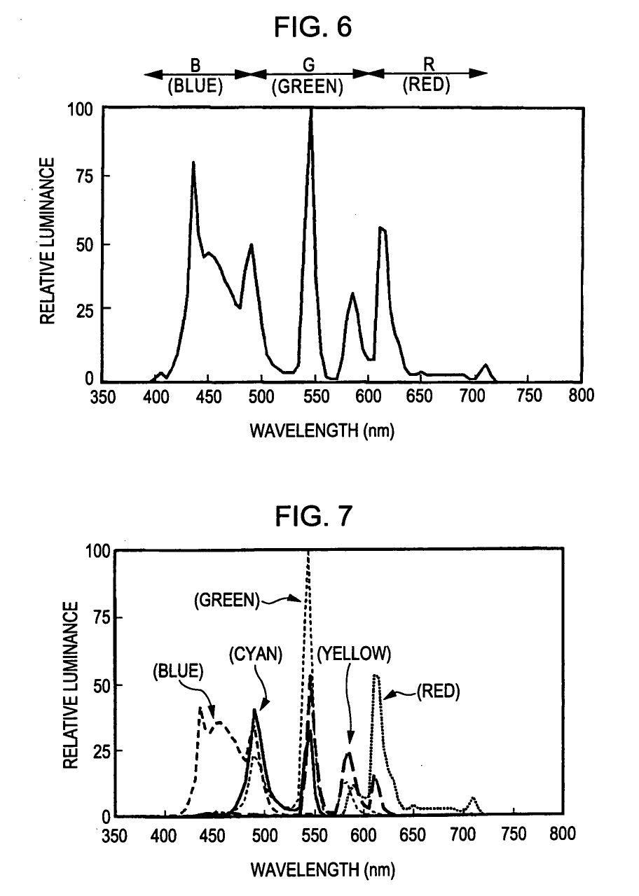

In the liquid crystal panel 3F having the above-described configuration, illumination light emitted from the backlight 13 in the A direction is derived as display light having a color light component of arbitrary luminance by the functions of the liquid crystal layer 11 and the color filter 12. FIG. 6 is a diagram showing spectral characteristics of the backlight 13 when a fluorescent tube is used for a light source. As shown in FIG. 6, the light source of the backlight 13 is a three-wavelength fluorescent tube in which a strong light-emission peak is distributed in the order of B (blue), G (green), and R (red) from a short wavelength band of visible light toward a long wavelength band thereof.

FIG. 7 is a diagram showing spectral characteristics of transmitted light in a case in which the liquid crystal panel is illuminated by the backlight 13 having the fluorescent tube. As shown in FIG. 7, in display light emitted from the liquid crystal panel 3F having the color filter 12 that is provided with the colored portions 12s of five colors, the luminance peaks of B (blue), C (cyan), G (green), Y (yellow), and R (red) can be observed.

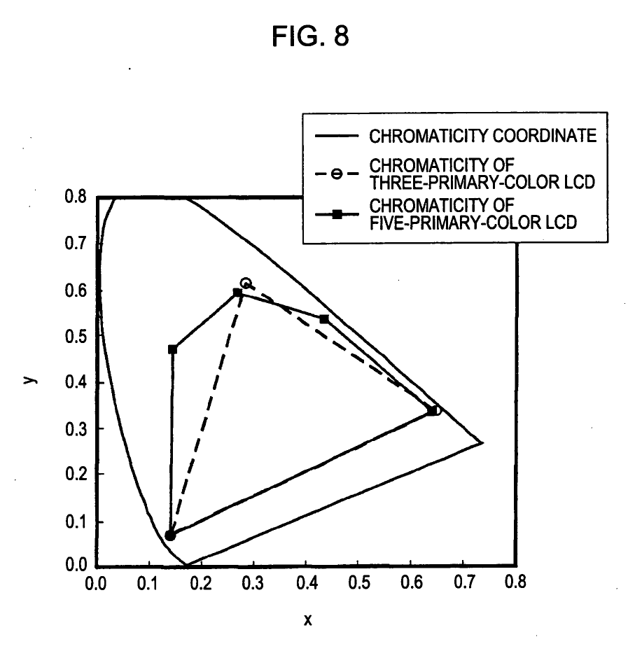

FIG. 8 is a diagram showing a calculation result of xy chromaticity from the spectral characteristics shown in FIG. 7. Further, FIG. 8 shows a calculation result of xy chromaticity in the liquid crystal panel having the color filter of three colors (R, G, and B). As shown in FIG. 8, the color reproduction range of the liquid crystal panel using the color filter of three colors is a triangular area defined by three points corresponding to R (red), G (green), and B (blue). On the contrary, in the liquid crystal panel 3F having the color filter 12 of five colors according to the present embodiment, the color reproduction range is a pentagonal area defined by five points including C (cyan) and Y (yellow), in addition to R, G, and B. Therefore, in the liquid crystal panel 3F according to the present embodiment, a large range of colors can be reproduced and thus display having superior expressiveness, such as color tone, sensibility, gloss, or the like, can be achieved as compared to the liquid crystal panel of the three primary colors.

The image display system 1 according to the present embodiment has a feature whereby the color filter 12 has the colored portion groups 12a, each having the colored portions 12s of five colors that are arranged in the zigzag pattern in the honeycomb in plan view. That is, each colored portion group 12a has a configuration in which two and three colored portions 12s are arranged in the honeycomb shape in the column direction, such that the liquid crystal panel has a configuration in which the display pixels are densely arranged without gaps. As a result, a bright display can be achieved with fidelity and high definition. In addition, the sub-pixels are arranged in the honeycomb shape (delta type), such that display irregularity can be prevented from occurring due to light interference caused by weak regularity between pixels, as compared to the general stripe type. Further, in the color filter 12, the black matrix 12b extends linearly only in the row direction of FIG. 4, such that the black matrix cannot be perceived when the panel is observed.

According to the present embodiment, the backlight 13 includes the light source using the fluorescent tube. The fluorescent tube may be a general three-wavelength fluorescent tube that is obtained by applying three kinds of fluorescent materials (RGB) in the tube. That is, when the backlight 13 is used for the illumination unit of the liquid crystal panel 3F for the five-primary-color display, a fluorescent tube that is obtained by applying four or five fluorescent materials in the tube does not need to be prepared, which results in an image display system with high image quality at low cost.

Further, though the backlight 13 includes the light source using the fluorescent tube in the present embodiment, a three-color LED (light-emitting diode) may be used. That is, when this backlight is used for the illumination unit of the liquid crystal panel 3F for the five-primary-color display, a four- or five-color LED does not need to be prepared, which results in an image display system with high image quality at low cost.

In addition, though the liquid crystal panel 3F is the transmissive liquid crystal panel in the present embodiment, a reflective liquid crystal panel or a transflective liquid crystal panel may be used as the liquid crystal panel 3F. In the present embodiment, the image display system 1 has the input unit 1A that serves as the imaging unit having the input sensor 2A. Alternatively, the input unit 1A may be a storage unit that stores image data and the transmission path that connects the storage unit and the output unit 1B may be an electrical communication line, such as a network line.

### Second Embodiment

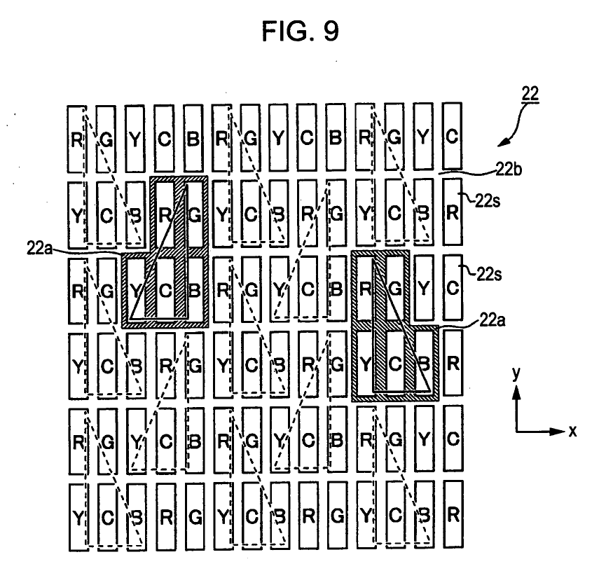

Next, a second embodiment of the invention will be described with reference to FIG. 9. According to the second embodiment, a liquid panel is different from the liquid crystal panel included in the image display system 1 shown in FIG. 1. That is, the liquid crystal according to the second embodiment has a color filter (image display region) 22 shown in FIG. 9.

The color filter 22 primarily has a plurality of colored portions 22s arranged in a row direction (x direction in the drawing) and a column direction (y direction in the drawing) and colored portions 22s of five primary colors (R, G, Y, C, and B) are periodically arranged in the row direction. The respective colored portions 22s are arranged in a matrix shape so as to form a rectangular shape in plan view. Therefore, a black matrix 22b that divides the respective colored portions 22s extends in a matrix shape in the x direction and the y direction in the drawing.

In addition, the colored portions 22s form colored portion groups 22a (colored portion groups indicated by triangles), each having five colored portions 22s for different colors. On the surface of the color filter 22, the colored portion groups 22a are arranged in a zigzag pattern in a honeycomb shape in plan view. According the present embodiment, each colored portion group 22a has three continuous colored portions 22s (Y, C, and B) in the row direction and two colored portions 22S (R and G) adjacent to the three colored portions 22s in the column direction. In addition, adjacent colored portion groups 22a in the row direction are arranged so as to be shifted by a ½ pixel and have reversed external shapes in the row direction. That is, the colored portion group 22a having a substantially L shape (a portion indicated by oblique lines on the right side of the drawing) and the colored portion group 22a having a substantially inverted-L shape (a portion indicated by oblique lines on the left side of the drawing) are alternately arranged in the y direction.

In addition, the pixels of the liquid crystal panel having the color filter 22 are arranged in a matrix shape, as shown in FIG. 9. Like the liquid crystal panel 3F shown in FIG. 3, the respective pixel electrodes 16 are two-dimensionally provided at locations overlapping the respective colored portions 22s of the color filter to constitute the respective sub-pixels. In addition, one display pixel has five sub-pixels corresponding to the colored portion group 22a.

According to the liquid crystal panel including the color filter 22 having the above-described configuration, the sub-pixels (colored portions 22s) are arranged in the matrix shape, a liquid crystal panel that can simplify the wiring structure and can be easily manufactured can be achieved at low cost, as compared to the liquid crystal panel in which the sub-pixels are arranged in the honeycomb shape (delta), like the above-described first embodiment. In addition, the colored portion groups 22a constituting the display pixels are arranged in the substantially honeycomb shape in the color filter 22 according to the second embodiment, and thus the display pixels can be arranged in the display region without gaps and thus the display can be achieved with high definition and high luminance.

Also in the color filter 22 according to the second embodiment, the arrangement of the respective colored portions 22s constituting the sub-pixels are not limited thereto, but various arrangements may be applied. In addition, the aspect ratio of the colored portion 22s (ratio of lengths between the long side (y direction) and the short side (x direction)) may be arbitrarily set.

### Third Embodiment

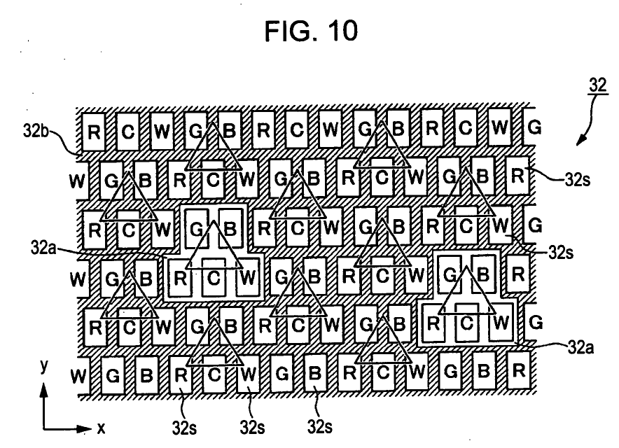

Next, a third embodiment of the invention will be described with reference to FIG. 10. A liquid crystal panel according to a third embodiment is different from the liquid crystal panel included in the image display system 1 shown in FIG. 1. That is, the liquid crystal panel according to the third embodiment includes a color filter (image display region) 32. FIG. 10 shows the two-dimensional configuration of the color filter 32.

The color filter 32 has colored portions 32s of four chromatic colors (R, G, B, and C) and a colored portion 32s of white (achromatic color or color of light source) are arranged in a honeycomb shape (delta type) in plan view. The white colored portion is provided, instead of the Y (yellow) colored portion of the color filter 12 according to the above-described first embodiment. That is, each colored portion group 32a, which includes five colored portions 32s and corresponds to the display pixel, has three colored portions (R, C, and W) arranged in the row direction and two colored portions (G and B) arranged adjacent to the three, colored portions.

In the liquid crystal panel including the color filter 32 having the above-described configuration, the four-primary-color display (R, G, B, and C) is performed, so that a display color range becomes narrow, as compared to the liquid crystal panel having the color filter 12 for the five-primary-color display shown in FIG. 4. However, in the liquid crystal panel according to the present embodiment, since the white sub-pixel is provided, the transmittance of the display pixel can be increased and the bright display can be achieved.

In addition, the present embodiment adopts the configuration in which the W (white) colored portion is provided, instead of the Y (yellow) colored portion from the colored portions of the color filter for the five colors according to the first embodiment shown in FIG. 4. However, kinds of colors of the colored portions 32s of the chromatic colors are not limited thereto. Of course, the combination of four colors, such as R, G, B, and Y may b used.

### Fourth Embodiment

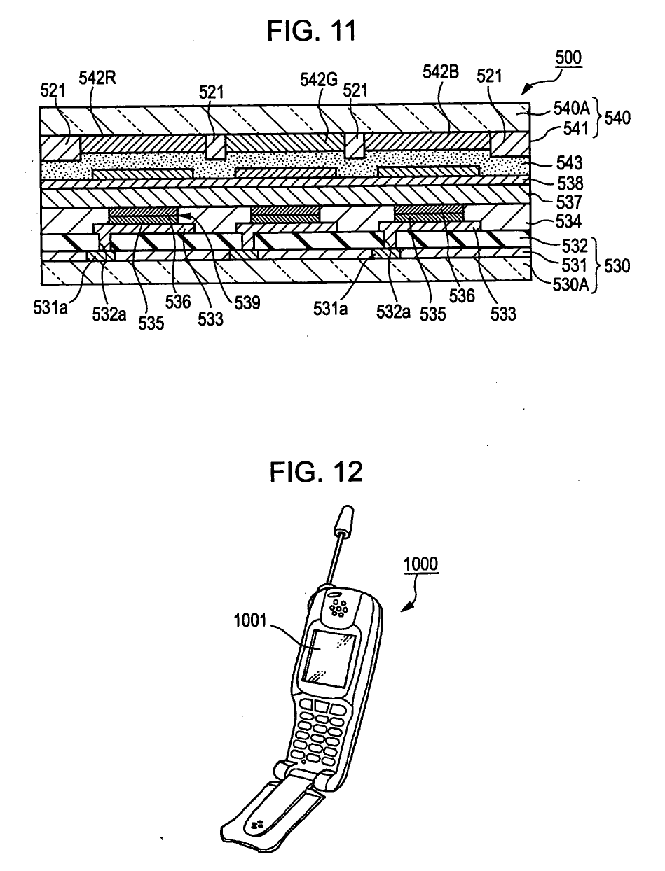

Next, a fourth embodiment of the invention will be described with reference to FIG. 11. Hereinafter, as an embodiment of an electro-optical device of the invention, an organic EL display device is exemplified in which sub-pixels primarily including EL elements are provided.

FIG. 11 is a diagram partially showing the configuration of an organic EL display device 500 according to the present embodiment. In the organic EL display device 500, the five-primary-color display can be performed, like the liquid crystal panel according to the above-described embodiment. In FIG. 11, only three adjacent sub-pixels are shown.

As shown in FIG. 11, the organic EL display device 550 is a top-emission-type full-color organic EL display device having the configuration in which an element substrate 530 with a plurality of EL elements (light-emitting elements) formed thereon and a counter substrate 540 with colored portions of five colors including colored portions 542R, 542G, and 542B of R (red), G (green), and B (blue) formed thereof are bonded to each other via an adhesive layer 543.

In the organic EL display device 500 according to the present embodiment, bank layers 534 that divide the respective pixels are provided on the element substrate 530, on which anodes (pixel electrodes) 533 are provided. In addition, in each region defined by two adjacent bank layers 534, an organic EL layer 539 is formed to have a hole injecting/transporting layer 535 and a light-emitting layer 536 including a white light-emitting material sequentially deposited thereon. That is, in the bank layer 534, an opening is formed at a location corresponding to each pixel, and the above-described organic EL layer 539 is formed at a location where the anode 533 is exposed through the opening. In addition, a cathode (counter electrode) 537 is provided so as to cover the bank layers 534 and the organic EL layers 539.

The present embodiment adopts the top emission structure in which light generated in the organic EL layer is derived from the cathode. Therefore, the cathode 537 is made of a co-deposition film of bathocupuroine (BCP) and cesium (Cs) is used and ITO is further deposited on the cathode 537 so as to impart conductivity. In addition, in order that light generated in the anode 533 is derived from the cathode, the cathode adopts the laminated structure of a metal material, such as Al or Ag, having high reflectance or, a light-transmission material, such as Al or ITO, and a metal material having high reflectance.

In addition, the cathode 537 is arranged so as to cover the exposed surfaces of the bank layer 534 and the organic EL layer 539 (light-emitting layer 536) and functions as a common electrode common to the respective pixels. In this case, it is also possible to use a cathode obtained by performing the film deposition of a metal having a low work function, such as Ca, Mg, Ba, Sr, or the like and a protective electrode made of Al, Ag, Au or the like to have the total thickness of not more than 50 nm.

In the element substrate 530, circuit element units 531 and inter-layer insulating films 532 are sequentially deposited on a substrate main body 530A made of glass or resin. On the inter-layer insulating films 532, the cathodes 533 are arranged in a matrix shape so as to correspond to the respective pixels. In the circuit element unit 531, various wiring lines, such as scanning lines or signal lines, storage capacitors (not shown), and TFTs 531 a serving as pixel switching elements are provided. According to the present embodiment, since the top emission structure is employed, the substrate main body 530A does not need to be transparent. For this reason, as regards the substrate main body 530A, translucent or nontransparent substrate, such as a semiconductor substrate, can be used.

The organic EL layer 539 has the hole injecting/transporting layer 535 and the white light-emitting layer 536 sequentially deposited from the bottom (pixel electrode).

As materials for forming the hole injecting/transporting layer 535, polymer materials can be suitably used, including polythiophene, polystyrenesulfonate, polypyrrole, polyaniline, and derivatives thereof. As materials for forming the white light-emitting layer 536 (light-emitting materials), polymeric light-emitting materials or low-molecular-weight organic light-emitting pigments, that is, light-emitting materials, such as various fluorescent materials or phosphorus materials, can be used. It is most preferably to use materials having the structure of arylenevinylene or polyfluorene.

According to the present embodiment, since the bank layer 534 having the opening provided to correspond to the formation region of the organic EL layer is provided as described above, the hole injecting/transporting layer 535 and the white light-emitting layer 536 can be suitably formed by using an inkjet method (liquid droplet ejection method). Therefore, it is preferable to use polymer materials suitable for the liquid droplet ejection method as the light-emitting materials. Specifically, it is possible to suitably use materials obtained by mixing polydeoxylfluorene (PFO) and MEH-PPV with a ratio of 9:1. In addition, according the present embodiment, the organic EL layer has the two-layered structure including the hole injecting/transporting layer and the light-emitting layer. Alternatively, an electron transporting layer or an electron injecting layer may be provided on the white light-emitting layer 536.

The substrate having the above-described configuration is sealed by the sealing material 538. Preferably, the sealing material 538 has a gas barrier property. For example, it is possible to suitably use a silicon oxide, such as SiO₂, a silicon nitride, such as SiN, or a silicon oxide nitride, such as SiOₓN_{y}. It is effective that a resin layer made of acryl, polyester, epoxy, or the like is deposited on an inorganic oxide layer. In addition, a protective film may be provided between the cathode 37 and the sealing material 38, if necessary.

On the other hand, in the counter substrate 540, a color filter 541 is provided on the light-transmission substrate main body 540A made of glass or resin. The color filter 541 may have the same configuration as the color filter 12 shown in FIG. 4 or the color filter 22 shown in FIG. 9. In the drawing, three kinds of colored portions 542R, 542G, and 542B of R, G, and B are divided by the bank layers (black matrix) to be two-dimensionally arranged. The opening portion of the bank layer 521 (formation region of colored portion) is provided at a location overlapping the opening of the bank layer 534 of the element substrate 530 side. Therefore, the respective colored portions 542R, 542G, and 542B are disposed so as to overlap the respective organic EL layers 539 of the element substrate 530 and constitute the sub-pixels in the organic EL display device 500.

In the organic EL display device according to the present embodiment, the color filter 541 has the configuration in which the display pixels, each having sub-pixels of five colors, are in a substantially honeycomb shape (delta arrangement) in the display region and are densely arranged without gaps. Therefore, in the organic EL display device according to the present embodiment, the five-primary-color display can be performed with high definition and high luminance, the color reproduction range can be expanded, and the display having superior expressiveness can be performed.

In addition, in the present embodiment, the case in which the light-emitting layer 536 outputs a white light component is described. However, it is possible to use the light-emitting layers 536 which emit a blue light component, a violet light component, or an ultraviolet light component. In this case, the colored portion provided in each sub-pixel includes a fluorescent material having a predetermined color conversion characteristic, such that a predetermined color light component (display light) can be outputted. Therefore, it is possible to easily constitute an organic EL display device for the five-primary-color display.

In addition, the organic EL display device according to the present embodiment relates to a method in which white light, ultraviolet light, or violet light emitted from the organic EL element is allowed to transmit the colored portions, thereby obtaining color light components and performing the color display. Alternatively, a method in which the organic EL elements constituting the sub-pixels of the organic EL display device have functions for emitting the respective color light components of R, G, B, C, and Y.

Electronic Apparatus

FIG. 12 is a perspective view showing an example of the configuration of an electronic apparatus according to the invention. In FIG. 12, a cellular phone 1000 includes a display unit 1001 having the liquid crystal panel according to the above-described embodiment or the organic EL display device. In addition, the electronic apparatus having the above-described configuration can have high fidelity by means of the electro-optical device according to the above-described embodiment and can perform the bright display.

The electro-optical device according to the embodiment can be suitably used for an image display unit of electronic apparatuses including an electronic book, a personal computer, a digital still camera, a television, a view-finder-type or monitor-direct-view-type video tape recorder, a car navigation device, a pager, an electronic organizer, an electronic calculator, a word processor, a workstation, a video phone, a POS terminal, and a touch panel. In any electronic apparatus, it is possible to provide the high-image-quality display with high definition, luminance, and fidelity.

What is claimed is:

1. An electro-optical device comprising:
a plurality of sub-pixels two-dimensionally arranged in a row direction of a display region and in a column direction thereof orthogonal to the row direction,
wherein each group of five sub-pixels constitutes a display pixel, including three sub-pixels that are arranged in the row direction and two sub-pixels that are adjacent to the three sub-pixels in the column direction, the sub-pixels in one display pixel outputting different color light components, and
wherein the display pixels are arranged two-dimensionally in a substantially honeycomb shape.

2. The electro-optical device according to claim 1,
wherein the sub-pixels have substantially rectangular shapes in plan view and are arranged in a square lattice shape in the display region.

3. The electro-optical device according to claim 2,
wherein two adjacent display pixels in the row direction have reversed external shapes.

4. The electro-optical device according to claim 1,
wherein the sub-pixels have rectangular shapes in plan view and are arranged in a honeycomb shape in the display region.

5. The electro-optical device according to claim 1, further comprising:
a color filter having a plurality of colored portions that are arranged so as to correspond to the respective sub-pixels,
wherein, from five colored portions included in each display pixel, four colored portions are chromatic colored portions and one colored portion is an achromatic colored portion or a colored portion having a color corresponding to a light source.

6. The electro-optical device according to claim 5,
wherein the chromatic colored portions include colored portions of red, green, and blue.

7. The electro-optical device according to claim 5,
wherein the chromatic colored portions include a colored portion of cyan, yellow, or magenta.

8. The electro-optical device according to claim 1,
wherein each sub-pixel includes a light-emitting element.

9. The electro-optical device according to claim 1, further comprising:
a liquid crystal panel that has a liquid crystal layer interposed between a pair of substrates.

10. A color filter comprising:
a plurality of colored portions two-dimensionally arranged in a row direction and in a column direction thereof orthogonal to the row direction;
wherein five colored portions constitute a colored portion group, including three colored portions that are arranged in the row direction and two colored portions that are adjacent to the three colored portions in the column direction, the colored portions in one colored portion group being different in color, and
wherein the colored portion groups are arranged two-dimensionally in a substantially honeycomb shape.

11. The color filter according to claim 10,
wherein the colored portions have substantially rectangular shapes in plan view and are arranged in a square lattice shape in plan view.

12. The color filter according to claim 11,
wherein adjacent colored portion groups in the row direction have reversed external shapes.

13. The color filter according to claim 10,
wherein the colored portions have substantially rectangular shapes in plan view and are arranged in a honeycomb shape in plan view.

14. An electronic apparatus comprising the electro-optical device according to claim 1.
